(19) United States
(12) Patent Application Publication
(10) Pub. No.: US 2025/0221251 A1
(43) Pub. Date: Jul. 3, 2025

(54) Display Device

(71) Applicant: LG Display Co., Ltd., Seoul (KR)

(72) Inventors: Eunwoo Lee, Paju-si (KR); Jaeho Choi, Gyeongju-si (KR)

(21) Appl. No.: 18/984,684

(22) Filed: Dec. 17, 2024

(30) Foreign Application Priority Data
Dec. 29, 2023 (KR) 10-2023-0196631

(51) Int. Cl. H10K 59/80

(52) U.S. Cl. CPC H10K 59/8722; H10K 59/873

(57) ABSTRACT

The present disclosure relates to a display device. The display device comprises a first substrate, a light emitting element disposed on a display area of the first substrate, an encapsulation layer disposed on the light emitting element, a second substrate disposed on the encapsulation layer and configured to face the first substrate, a dam structure disposed between the first substrate and the second substrate and disposed in a non-display area surrounding the display area, and a filling layer disposed to fill a space between the encapsulation layer and the second substrate, the dam structure comprising a matrix resin, and a capsule dispersed in the matrix resin and configured to include a redox dye.

### CROSS-REFERENCE TO RELATED APPLICATION

This application claims the priority of Republic of Korea Patent Application No. 10-2023-0196631 filed on Dec. 29, 2023, which is hereby incorporated by reference in its entirety.

### BACKGROUND

### Field

The present disclosure relates to a display device, and particularly, a display device that minimizes or at least reduces damage to a display panel, caused by oxygen drawn from the outside, and secures excellent reliability.

### Description of the Related Art

Display devices may be used for various types of devices such as a television (TV), a monitor, a tablet computer, a navigator, a gaming console, a mobile phone and the like. Display devices comprise a variety of ones such as a liquid crystal display (LCD) device, an organic light emitting display (OLED) device and the like.

Organic light emitting display devices are self-emitting devices that ensure low power consumption, high response speed, high light emission efficiency, high luminance and a wide viewing angle. In the case of an organic light emitting display device, moisture or oxygen drawn from the outside infiltrates into the display device and degrades a variety of organic layers and elements, causing failures.

### SUMMARY

Specifically, in the case where functional layers are formed based on deposition in the state where foreign substances are present at a time when an organic light emitting display device is manufactured, a failure in the deposition occurs due to the foreign substances, creating a crack or a seam. When moisture or oxygen is drawn from the outside, the moisture or oxygen infiltrates into an organic light emitting diode through the crack or seam, causing a failure of dark spots.

To prevent this from happening, a moisture absorber is dispersed in an organic layer of a dam structure or a filling layer and the like, or a cathode having relatively high gas barrier properties is deposited to entirely cover an organic light emitting layer thereunder, thereby delaying the infiltration of moisture, but the organic light emitting display device has inferior oxygen prevention or delay properties and is vulnerable to a failure caused by the inferior properties.

To solve the above problems, the objective of the present disclosure is to provide a display device that can minimize or at least reduce an oxygen-induced failure of a display panel and secure excellent reliability.

Objects of the present disclosure are not limited to the above-mentioned objects, and other objects, which are not mentioned above, can be clearly understood by those skilled in the art from the following descriptions.

A display device of one embodiment comprises a first substrate, a light emitting element disposed on a display area of the first substrate, an encapsulation layer disposed on the light emitting element, a second substrate disposed on the encapsulation layer and configured to face the first substrate, a dam structure disposed between the first substrate and the second substrate and disposed in a non-display area surrounding the display area, and a filling layer disposed to fill a space between the encapsulation layer and the second substrate, the dam structure comprising a matrix resin, and a capsule dispersed in the matrix resin and configured to include a redox dye.

Other detailed matters of the exemplary embodiments are included in the detailed description and the drawings.

In the display device, the capsule comprising the redox dye is included in the dam structure, and the redox dye absorbs oxygen to prevent and delay the infiltration of the oxygen, thereby minimizing or at least reducing a failure caused by the oxygen.

In the display device, a moisture absorber is further included in the dam structure, to prevent and delay the infiltration of moisture and oxygen, thereby securing excellent reliability.

In the display device, a photosensitizer and a sacrificial electron donor as well as the redox dye may be further included in the capsule of the dam structure. Accordingly, the inflow of oxygen may be continuously prevented based on the oxidation and reduction of the redox dye at a time of irradiation of external light.

In the display device, a plurality of light sources may be further included on a housing member in such a way that the plurality of light sources overlaps the non-display area, and oxidation and reduction reactions of the redox dye are induced by light irradiate from the plurality of light sources to prevent the inflow of oxygen continuously.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to one embodiment;

FIG. 2 is a cross-sectional view along I-I′ of FIG. 1 according to one embodiment;

FIG. 3 is a cross-sectional view of a capsule included in a dam structure, in the display device according to one embodiment one embodiment;

FIG. 4 is cross-sectional views for describing a state before and after photoactivation of the display device according to one embodiment one embodiment;

FIG. 5 is a reaction formula for describing oxidation and reduction reactions of methylene blue according to one embodiment;

FIG. 6 is a plan view of a display device according to another embodiment; and

FIG. 7 is a cross-sectional view along II-II′ of FIG. 6 according to one embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

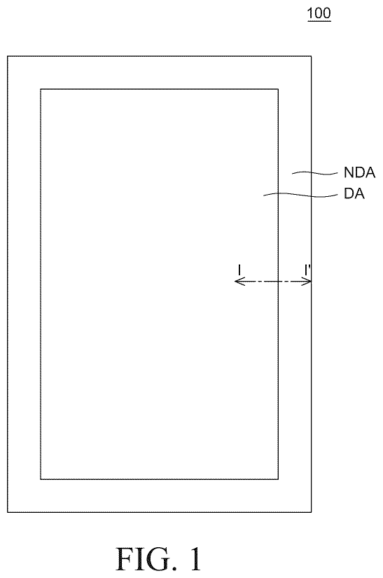

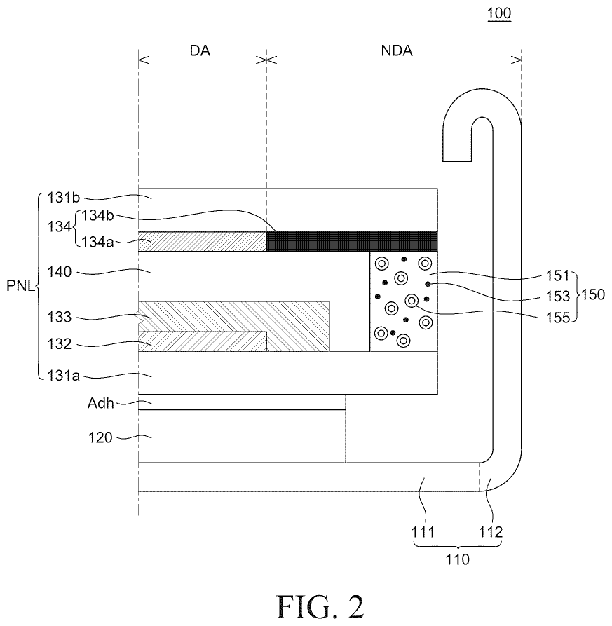

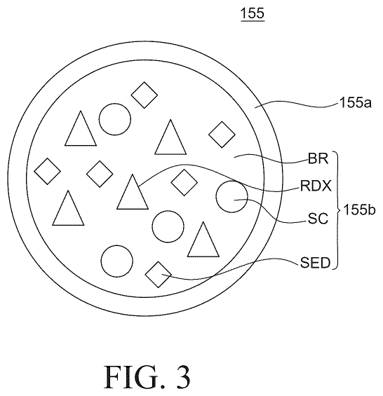

FIG. 1 is a plan view of a display device according to one embodiment, FIG. 2 is a cross-sectional view of the display device according to one embodiment, and FIG. 3 is a cross-in sectional view of a capsule according to one embodiment.

Referring to FIGS. 1-3, a display device 100 of the present disclosure comprises a display panel PNL, a housing member 110, a lower protection member 120, and an adhesive layer Adh. The display panel PNL comprises a first substrate 131a, a light emitting element (for example, a light emitting diode) 132, an encapsulation layer 133, a second substrate 131b, a color filter layer 134, a filling layer 140, and a dam structure 150.

The display panel PNL comprises a display area DA and a non-display area NDA. The display area DA is an area where a plurality of pixels are disposed and where an image is substantially displayed. In the display area DA, a pixel comprising a light emitting area for displaying an image, and a driving circuit for driving a pixel may be disposed. The non-display area NDA is disposed to surround the display area DA. The non-display area NDA is an area where an image is not displayed and where a variety of lines for driving the pixel and the driving circuit disposed in the display area DA, a driving IC, a printed circuit board and the like are disposed.

The first substrate 131a is a substrate supporting various types of elements constituting the display panel PNL. The first substrate 131a, for example, may be a glass substrate or a plastic substrate. For example, the plastic substrate may be made of a material selected from polyimide, polyethersulfone, polyethylene terephthalate and polycarbonate, but not limited thereto.

The first substrate 131a is a substrate on which a thin film transistor is disposed. In this regard, the first substrate 131a may be referred to as a thin film transistor array substrate. For example, a driving thin film transistor, a switching thin film transistor, a capacitor and the like may be disposed on the first substrate 131a.

The thin film transistor comprises a gate electrode, an active layer, a source electrode and a drain electrode. For example, the active layer is disposed on the first substrate 131a, and a gate insulation layer for insulating the active layer from the gate electrode is disposed on the active layer. Additionally, an interlayer insulation layer for insulating the gate electrode from the source electrode and the drain electrode is disposed on the substrate. The source electrode and the drain electrode respectively contacting the active layer are formed on the interlayer insulation layer. A planarization layer may be disposed on the thin film transistor. The planarization layer planarizes the upper surface of the thin film transistor. The planarization layer may comprise a contact hole for connecting the thin film transistor and an anode electrically.

Taking the light emitting element being a light emitting diode as an example, but not limited thereto. The light emitting diode 132 is disposed on the first substrate 131a on which the thin film transistor is disposed. The light emitting diode 132 is disposed in an area corresponding to the display area. The light emitting diode 132 may comprise an anode, an organic light emitting stack and a cathode.

The anode as an element for supplying holes to the organic light emitting layer is formed of an electrically conductive material of high work function. The anode may be formed in a separate manner for each sub pixel.

The cathode is disposed on the anode. The cathode may be formed of a metallic material of low work function to supply electrons smoothly to the organic light emitting layer. The cathode may be shaped into a single layer on the anode, without being patterned. That is, the cathode may not be formed in a separate manner for each sub pixel area, but shaped into a continuous single layer.

The organic light emitting stack is disposed between the anode and the cathode. The organic light emitting stack may comprise an organic light emitting layer. The organic light emitting layer is a layer that emits light based on a coupling of electrons and holes. The organic light emitting layer may be formed in a separate manner for each sub pixel, or shaped into a continuous single layer across a plurality of sub pixels entirely. Additionally, the organic light emitting stack may further comprise one or more of a hole injection layer, a hole transport layer, an electron transport layer, and an electron injection layer. For example, the organic light emitting stack may be comprised of a hole injection layer disposed on the anode, a hole transport layer disposed on the hole injection layer, an organic light emitting layer disposed on the hole transport layer, an electron transport layer disposed on the organic light emitting layer, and an electron injection layer disposed on the electron transport layer.

The encapsulation layer 133 is disposed on the light emitting diode 132. The encapsulation layer 133 may prevent or at least reduce the degradation of the light emitting diode 132, caused by moisture or oxygen. Additionally, the encapsulation layer 133 planarizes the upper surface of the light emitting diode 132. The encapsulation layer 133 may be formed of an organic insulation material and/or an inorganic insulation material. The encapsulation layer 133 may have a single-layered structure or a multi-layered structure. For example, the encapsulation layer 133 may have a multi-layered structure in which an inorganic layer formed of an inorganic insulation material and an organic layer formed of an organic material are stacked. For example, the encapsulation layer 133 may be comprised of at least one organic layer and at least three inorganic layers and have a multi-layered structure in which an inorganic layer and an organic layer are stacked alternately. Specifically, the encapsulation layer, for example, may have a triple-layered structure in which a first inorganic layer, an organic layer and a second inorganic layer are included, but not be limited thereto.

The second substrate 131b facing the first substrate 131a is disposed on the encapsulation layer 133. The second substrate 131b protects the light emitting diode 132 from an external impact or moisture and the like. The second substrate 131b is a substrate that has a color filter layer 134. In this regard, the second substrate 131b may be referred to as a color filter array substrate.

The color filter layer 134 is disposed on one surface of the second substrate 131b facing the first substrate 131a. The color filter layer 134 comprises a plurality of color filters 134a and a black matrix 134b. Each of the plurality of color filters 134a may be disposed in the display area DA to correspond to the light emitting area of the light emitting diode 132. Each of the plurality of color filters 134a outputs light emitted from the organic light emitting layer of the light emitting diode 132 in the form of light of a color corresponding to each of the plurality of subpixels.

The black matrix 134b is disposed in the non-display area NDA and the display area DA. The black matrix 134b is disposed to correspond to the non-display area NDA, thereby preventing the leakage of light and preventing lines or a driving IC and the like disposed in the non-display area NDA from being recognized from the outside. Additionally, the black matrix 134b is disposed to partition between each of the plurality of color filters 134a in the display area. That is, the black matrix 134b is disposed to correspond to the non-display area of the light emitting diode 132 in the display area DA and prevents or at least reduces a mixture of colors between adjacent sub pixels.

The filling layer 140 is disposed between the encapsulation layer 133 and the color filter layer 134. The filling layer 140 fills a space between the encapsulation layer 133 and the color filter layer 134. The filling layer 140 bonds the first substrate 131a and the second substrate 131b. Accordingly, the filling layer 140 may be formed of a transparent organic layer having adhesion properties. For example, the filling layer 140 may be formed of an acryl-based resin, an epoxy-based resin and the like, but not limited thereto.

When necessary, the filling layer 140 may further comprise a moisture absorber selectively. The moisture absorber may prevent or at least reduce the degradation of the light emitting diode 132, caused by moisture infiltrating from the outside, by absorbing the moisture.

The dam structure 150 is disposed between the first substrate 131a and the second substrate 131b. The dam structure 150 is disposed between the first substrate 131a and the second substrate 131b in such a way that the dam structure 150 overlaps the non-display area NDA. The dam structure 150 is disposed at the edges of the first substrate 131a and the second substrate 131b to prevent or at least reduce the filling layer 140 from leaking to the outside. That is, the dam structure 150 seals the filling layer 140. Additionally, the dam structure 150 prevents or at least reduces the infiltration of moisture or oxygen into the side of the display device 100 from the outside and delays the degradation of the light emitting diode 132. Further, the dam structure 150 may comprise a material having adhesion properties. Accordingly, the dam structure 150 bonds the first substrate 131a and the second substrate 131b.

The dam structure 150 comprises a matrix resin 151 and a capsule 155 comprising redox dye RDX. The redox dye RDX is oxidated by oxygen. Accordingly, in the case where oxygen is drawn into the dam structure 150 from the outside, the oxygen reacts with the redox dye RDX and is prevented from flowing into the display area DA. Description in relation to this is provided hereinafter.

The lower protection member 120 is disposed on the back surface of the display panel PNL. The lower protection member 120 is disposed on the back surface of the first substrate 131a. The lower protection member 120 supports the display panel PNL and protects the display panel PNL from an external impact. The lower protection member 120 may perform heat dissipation. Accordingly, the lower protection member 120 may be made of a metallic material for heat dissipation or comprise a heatsink.

The lower protection member 120 may adhere to the back surface of the display panel PNL with the adhesive layer Adh. Thus, the display panel PNL may be fixed without being pushed or escaped. An adhesive insulation tape, a thermally conductive adhesive tape, an adhesive pad and a double-sided tape may be used as the adhesive layer Adh, and an adhesive resin may also be used as the adhesive layer Adh.

The housing member 110 is disposed on the back surface of the lower protection member 120. The housing member 110 accommodates and modularizes the display panel PNL. The housing member 110 has a bend structure to form a storage space. The housing member 110, for example, comprises a first portion 111 disposed under the display panel PNL, and a second portion 112 bent from the first portion 111 to cover at least a portion of the side surface of the display panel PNL. Accordingly, the display panel PNL may be stored in a space formed by the first portion 111 and the second portion 112. The housing member 110 may be made of a metallic material such as aluminum, aluminum alloy, stainless steel, electro galvanized steel and the like, but not limited thereto. In the case where the housing member 110 is made of a material having heat dissipation properties, the heatsink may be omitted.

Hereinafter, the dam structure 150 is specifically described with reference to FIGS. 2 and 3. Referring to FIG. 3, the dam structure 150 comprises a matrix resin 151, a moisture absorber 153, and a capsule 155.

The matrix resin 151 provides adhesive properties and disperses the capsule 155 and the moisture absorber 153. For example, the matrix resin 151 may use one or more selected from an acryl-based resin, an epoxy-based resin, a silicon-based resin, and the like, but not be limited thereto.

The moisture absorber 153 absorbs moisture drawn into the display panel PNL from the outside and prevents or at least reduces the degradation of the light emitting diode 132 and the like, caused by moisture. The moisture absorber 153, for example, may use at least one of a chemical absorber such as calcium oxide, barium oxide, strontium oxide, magnesium oxide, lithium sulfate, sodium sulfate, calcium sulfate, magnesium sulfate, cobalt sulfate, gallium sulfate, titanium sulfate, nickel sulfate and the like, and a physical absorber such as zeolite, porous silica, activated carbon and the like, but not be limited thereto. Depending on the design structure or configuration of the display device 100, the moisture absorber 153 may be omitted if reliability is ensured only with the moisture barrier properties of the matrix resin 151 itself.

The capsule 155 comprises a core 155b and a shell 155a. The shell 155a is formed to surround the core 155b. The shell 155a is formed to surround the core 155b so that elements constituting the core 155b may be capsulized. Accordingly, the shell 155a may be made of a crosslinked network-shaped polymer so that the shape of the capsule may be maintained reliably. For example, the shell may be made of a crosslinked hydrophilic polymer. The hydrophilic polymer, for example, may be selected from polyvinyl alcohol, polyethylene-vinyl alcohol, polyhydroxy alkyl methacrylate and a copolymer comprising one or more thereof.

The core 155b comprises a base resin BR, redox dye RDX, a photosensitizer SC, and a sacrificial electron donor SED.

The base resin BR disperses redox dye RDX, a photosensitizer SC, and a sacrificial electron donor SED evenly into the core 155b. The base resin BR may be made of a hydrophilic polymer. The hydrophilic polymer, for example, may be selected from polyvinyl alcohol, polyethylene-vinyl alcohol, polyhydroxy alkyl methacrylate and a copolymer comprising one or more thereof.

The base resin BR included in the core 155b may be made of the same hydrophilic polymer as the shell 155a. However, the base resin BR is made of a hydrophilic polymer of a non-crosslinked linear structure. As described above, the redox dye RDX is oxidated by oxygen and prevents the degradation of the light emitting diode 132 and the like, caused by oxygen drawn from the outside. In the case where the redox dye RDX is oxidated by oxygen as described above, water (H₂O) is generated, and the hydrophilic polymer absorbs the generated water. Accordingly, the hydrophilic polymer may prevent or at least reduce moisture generated after oxidation of the redox dye RDX from infiltrating into the display area DA. Further, as described above, the shell 155a comprises a crosslinked hydrophilic polymer. Accordingly, the shell 155a may also absorb water generated after oxidation of the redox dye and prevent or at least reduce the water from infiltrating into the display area DA.

In one embodiment, the shell 155a may be made of crosslinked polyvinyl alcohol, and the base resin BR may be made of non-crosslinked polyvinyl alcohol, and at this time, the shell and the base resin may secure excellent moisture absorption properties. However, the shell and the base resin are not limited thereto.

The redox dye RDX is oxidated by reacting with oxygen. Additionally, the oxidated redox dye RDX may be reduced by hydrogen. The redox dye RDX have different colors in an oxidated state and a reduced state. For example, the redox dye RDX may comprise one or more selected from methylene blue, safranin, resorufin and indigo carmine, but not be limited thereto. For example, in the case where methylene blue in a colorless state is oxidated, methylene blue is colored bluish, and in the case where methylene blue is reduced again, methylene blue becomes colorless. Safranin and resorufin may be respectively colored reddish at a time of oxidation, and indigo carmine may be colored bluish at a time of oxidation.

As described above, oxygen may continue to be consumed by using the properties of the redox dye RDX oxidated by oxygen and reduced by hydrogen. In the case where high reliability is required, to reduce the redox dye RDX oxidated by oxygen again, the core 155b may be further provided with a photosensitizer SC and a sacrificial electron donor SED.

The photosensitizer SC may be a semiconductor material that adsorbs ultraviolet rays and/or visible light. Accordingly, the photosensitizer SC is excited and generates electrons, when absorbing ultraviolet rays and/or visible light irradiated from the outside. Light for exciting the photosensitizer SC may be irradiated separately outside the display panel PNL, or light emitted from the light emitting diode 132 may be used as light for exciting the photosensitizer SC. Also, a dummy light emitting part may be formed in the non-display area NDA adjacent to the display area DA, and light emitted from the dummy light emitting part may be used as light for exciting the photosensitizer SC. For example, the photosensitizer SC may absorb ultraviolet rays of wavelengths from 300 nm to 400 nm or visible light of wavelengths of 500 nm or less. Specifically, the photosensitizer SC may comprise one or more selected from TiO₂ and nitrogen-doped TiO₂, for example.

The sacrificial electron donor SED is reduced by an electron generated by the excitation of the photosensitizer SC to generate a hydrogen ion. The hydrogen ion generated as described above reduces the redox dye RDX oxidate by oxygen. Accordingly, the redox dye RDX may fall into a state in which the redox dye RDX reacts again with oxygen. Based on the above-described theory, the capsule 155 included in the dam structure 150 may continue to consume oxygen, to prevent oxygen-induced degradation of the display panel PNL.

For example, the sacrificial electron donor SED may comprise one or more selected from glycerol, glucose and triethanolamine. Glycerol, glucose and triethanolamine may be reduced by the electron generated by excitation of the photosensitizer SC, to generate a hydrogen ion.

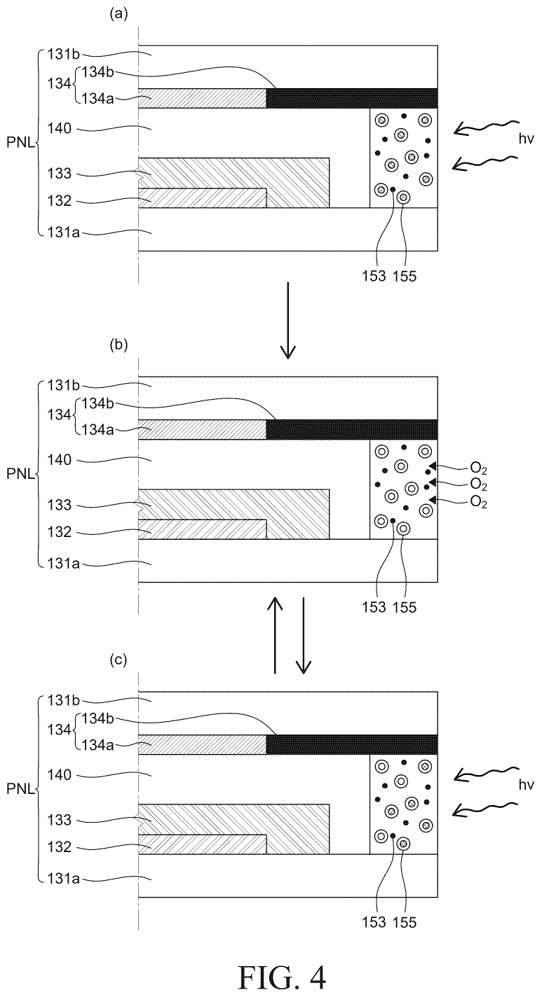

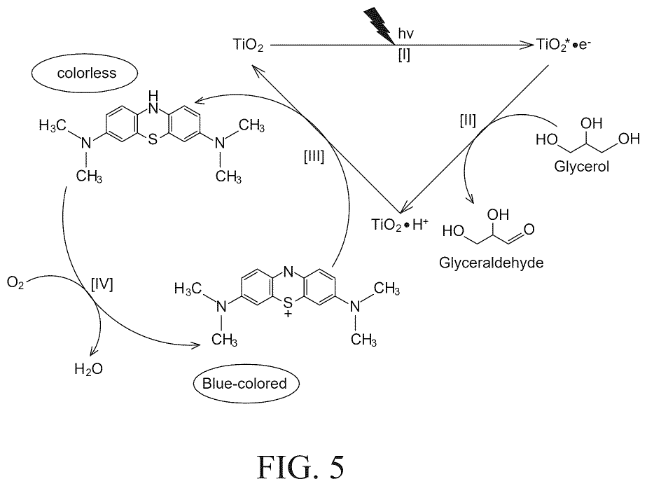

Hereinafter, the theory in which oxygen is consumed by the redox dye RDX is specifically described with reference to FIGS. 4 and 5 together. FIG. 4 is cross-sectional views for describing a state before and after photoactivation of the display device according to one embodiment. FIG. 5 is a reaction formula for describing oxidation and reduction reactions of methylene blue according to one embodiment. For example, in FIGS. 4 and 5, the redox dye RDX is methylene blue, the photosensitizer SC is TiO₂, and the sacrificial electron donor SED is glycerol for convenience of description, but not limited thereto.

Referring to part (a) of FIG. 4, the capsule 155 included in the dam structure 150 is also bluish initially. Methylene blue is ordinarily bluish and is in an oxidated state at room temperature. Accordingly, the capsule 155 of the dam structure 150 is also bluish. A bluish methylene blue in an oxidated state does not react with oxygen. Thus, a process of activating methylene blue into a colorless reduced state where methylene blue can consume oxygen is required.

In the case where photoactivation is performed by irradiating light hv to the display device 100 in the state of part (a) of FIG. 4, the state of part (a) of FIG. 4 turns into the state of part (b) of FIG. 4. Specifically, in the case where light hv is irradiated to the display device 100 in the state of part (a) of FIG. 4, bluish methylene blue is reduced and becomes colorless as shown in part (b) of FIG. 4. Accordingly, the capsule 155 in the dam structure 150 is not bluish.

In the state of part (b) of FIG. 4, colorless methylene blue reduced based on photoactivation is present in the dam structure 150. As described above, colorless methylene blue in a reduced state may react with oxygen (O₂) and be oxidated.

In the case where oxygen (O₂) is drawn from the outside into the dam structure 150 in a photo-activated state of part (b) of FIG. 4, a part of methylene blue having reacted with oxygen (O₂) is oxidated and becomes bluish as shown in part (c) of FIG. 4. Accordingly, the capsule 155 also becomes bluish. Thus, after photoactivation, the capsule 155 that becomes bluish because of drawn oxygen (O₂), and the capsule 155 that is colorless since methylene blue remains reduced may coexist.

As the ratio of a capsule 155 colored blue due to oxygen increases, the ability to consume oxygen may decrease. Accordingly, in the case where light hv is irradiated again to the display device 100 in the state of part (c) of FIG. 4, the state of part (c) of FIG. 4 may turn into the state of part (b) of FIG. 4. That is, as light hv is irradiated in the state of part (c) of FIG. 4, bluish methylene blue in an oxidated state may be reduced and become colorless again as shown in part (b) of FIG. 4. Thus, it is possible to continuously delay the inflow of oxygen.

Hereinafter, oxidation and reduction reactions of methylene blue are specifically described with reference to FIG. 5 together.

Referring to reaction formula I of FIG. 5, as light hv is irradiated from the outside, TiO₂ as a photosensitizer is excited and generates an electron (e−). The electron generated as described above reduces glycerol as a sacrificial electron donor and generates glyceraldehyde and a hydrogen ion (H+), as shown in reaction formula II. Then referring to reaction formula III, the generated hydrogen ion (H+) reduces bluish methylene blue in an oxidated state. Accordingly, the bluish methylene blue in an oxidated state turns into colorless methylene blue in a reduced state.

That is, as light hv is irradiated from the outside, methylene blue that is bluish initially is activated to colorless methylene blue in a reduced state in the processes of reaction formulas I-III.

The colorless methylene blue in a reduced state, as shown in reaction formula IV of FIG. 5, is oxidated and becomes bluish again as oxygen is drawn into the dam structure 150. Accordingly, the oxygen drawn into the dam structure 150 may be consumed and removed in the oxidation of colorless methylene blue.

Continuously referring to reaction formula IV of FIG. 5, water (H₂O) as a byproduct of the oxidation of methylene blue is generated. As described above, the water is adsorbed into a hydrophilic polymer constituting the base resin BR of the core 155b and the shell 155a or into a moisture absorber dispersed in the dam structure 150, and is not drawn into the display area DA.

Methylene blue that reacts with oxygen drawn into the dam structure 150 and is oxidated may be reduced again and become colorless in reaction formulas I-III of FIG. 5. Accordingly, the colorless methylene blue may react again with oxygen drawn into the dam structure 150 and consume the oxygen again. That is, as light capable of exciting TiO₂ as a photosensitizer SC is irradiated from the outside, methylene blue oxidated in reaction formulas I-III may be reduced again and continue to delay the infiltration of oxygen.

In FIGS. 4 and 5, the redox dye RDX is methylene blue, the photosensitizer SC is TiO₂, and the sacrificial electron donor SED is glycerol, for example, but not limited thereto, and obviously, another redox dye, another photosensitizer and another sacrificial electron donor may be used and operate based on the same theory and mechanism.

Thus, the display device 100 of one embodiment may prevent and delay the infiltration of oxygen drawn from the outside into the display panel PNL. Accordingly, oxygen-induced degradation of the light emitting diode 132, the thin film transistor and the like may be prevented, and a highly reliable display device 100 may be provided.

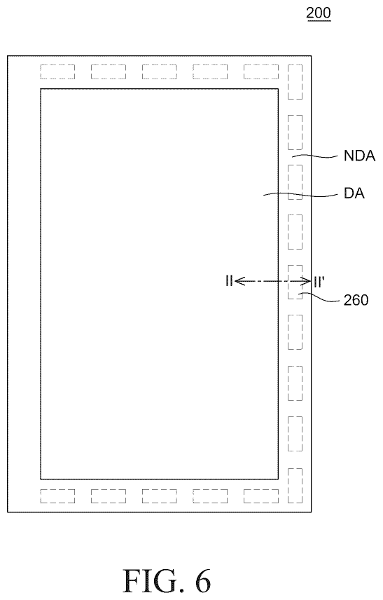

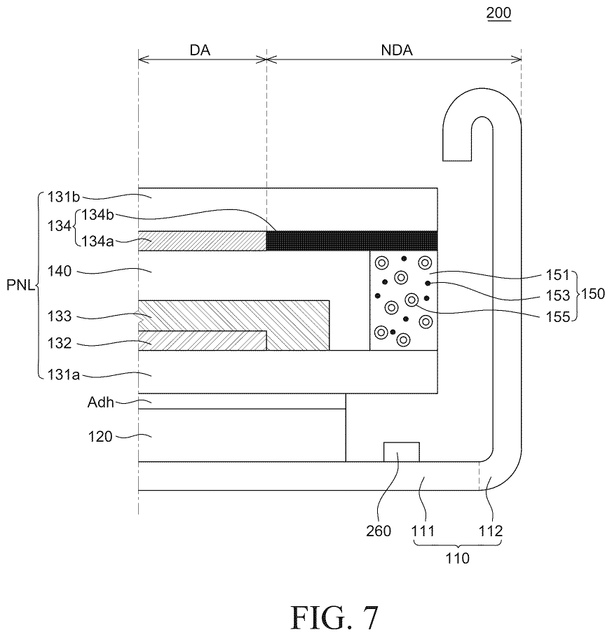

Hereinafter, a display device of another embodiment is described with reference to FIGS. 6 and 7. FIG. 6 is a plan view of a display device according to another embodiment, and FIG. 7 is a cross-sectional view along II-II′ of FIG. 6 according to one embodiment.

Referring to FIGS. 6 and 7, a display device 200 comprises a display panel PNL, a plurality of light sources 260, a housing member 110, a lower protection member 120, and an adhesive layer Adh. The display panel PNL comprises a first substrate 131a, a light emitting diode 132, an encapsulation layer 133, a second substrate 131b, a color filter layer 134, a filling layer 140, and a dam structure 150. The display device illustrated in FIGS. 6 and 7 is substantially the same as the display device described with reference to FIGS. 1-5 except that the display device of FIGS. 6 and 7 further comprises a plurality of light sources 260. Accordingly, their common elements are not described.

As described above, light needs to be irradiated, so that the redox dye RDX included in the capsule 155 of the dam structure 150 may continue to delay the inflow of oxygen by changing an oxidated state and a reduced state. In the display device 100 of FIGS. 1-5, an oxidation reaction and a reduction reaction of the redox dye may be performed by light separately irradiated from the outside, or light emitted from the light emitting diode 132.

The display device 200 illustrated in FIGS. 6 and 7 comprises a plurality of light sources 260 on the housing member 110. Each of the plurality of light sources 260 is disposed on the housing member 110 in such a way that the light sources 260 overlap the non-display area NDA. Accordingly, the redox dye RDX included in the capsule 155 of the dam structure 150 may be photo-activated more rapidly and readily by light emitted from the light source 260. That is, since the plurality of light sources 260 is provided in the display device 200, the state of the redox dye RDX may be transitioned between an oxidated state and a reduced state rapidly.

For example, each of the plurality of light sources 260 may be an LED. Specifically, each of the plurality of light sources 260 may use an LED of wavelengths from 300 nm to 400 nm, for example, but not be limited thereto.

Each of the plurality of light sources 260 is disposed on the housing member 110 in such a way that the light sources 260 overlap the non-display area NDA. Each of the plurality of light sources 260 may be disposed on the first portion 111 of the housing member 110. The plurality of light sources 260 is provided to photo-activate the redox dye RDX in the capsule 155 and transition the state of the redox dye between an oxidated state and a reduced state. Accordingly, the plurality of light sources 260 is disposed to overlap the non-display area NDA where the dam structure 150 is placed.

The non-display area NDA is shaped into a frame to surround the display area DA. The plurality of light sources 260 may be disposed on the first portion 111 of the housing member 110, to overlap three of four surfaces of the non-display area NDA surrounding the display area DA.

As described above, in the non-display area NDA, a variety of lines for driving pixels and driving circuits, driving ICs, a printed circuit board and the like are disposed. For example, a gate driving IC may be disposed at least one of the four surfaces of the non-display area NDA. In the case where the gate driving IC is disposed on at least one surface of the non-display area NDA as described above, a driving failure may occur due to the interference of the circuit when the driving IC overlaps the light source. To prevent interference between light sources and a driving IC such as a gate driving IC, disposed in the non-display area NDA, and the circuit, the plurality of light sources 260 may be disposed only on three of the four surfaces of the non-display area NDA where a driving IC is not disposed, but not limited thereto. If a driving failure does not occur due to interference between circuits depending on the design structure or configuration of a display device 200, the plurality of light sources 260 may be disposed on all the four surfaces of the non-display area NDA.

In the display device 200 of another embodiment, the capsule 155 comprising the redox dye RDX is dispersed in the dam structure 150. Accordingly, in the case where oxygen is drawn from the outside, the redox dye RDX may be oxidated to prevent and delay the infiltration of oxygen into the display panel PNL. Further, the display device 200 may comprise the plurality of light sources 260 so that the photoactivation of the redox dye RDX and a transition between an oxidated state and a reduced state of the redox dye RDX may be performed rapidly. Thus, the degradation of the light emitting diode 132 and the thin film transistor and the like, caused by oxygen, may be prevented, and a highly reliable display device 200 may be provided.

Hereinafter, the above-described effects are specifically described with reference to embodiments. However, the embodiments are provided only as examples, and are not intended to limit the scope of the present disclosure.

### [Manufacturing Example: Manufacturing of Capsule]

A solution of 15 wt % of solid content was manufactured. The solid content included polyvinyl alcohol of a 80,000 g/mol molecular weight and a 90% saponification degree, TiO₂ (of a diameter of 10 nm-50 nm), methylene blue, and glycerol respectively at a ratio of 5:2:5:3. Then an isooctane solution including 2 wt % of Span80 as a dispersant was prepared. Then 50 wt % of the previously manufactured solution was added dropwise to 100 wt % of the isooctane solution and emulsified with a high-pressure disperser emulsifier to have a 1 μm to 5 μm size. A 40° C. toluene solution in which 5 wt % of glutaraldehyde as a crosslinker was dissolved was prepared. Acetic acid was added dropwise to the toluene solution, to adjust pH to 4. The emulsified solution manufactured previously was added dropwise to the toluene solution the PH of which was adjusted and stirred for 24 hours, to manufacture a micro-sized capsule. The micro capsule manufactured as described above was washed with a solution in which water and toluene were mixed at a volumetric ratio of 1:1 and then dried.

### [Experimental Example]

To see the reactivity of the capsule, the manufactured capsule was dispersed in a matric resin and coated the matrix resin, and a film was manufactured. The film manufactured as described above was bluish. It turned out that the bluish film was reduced with hydrogen and became colorless. Further, it turned out that the film that became colorless was oxidated with oxygen and became bluish again.

The exemplary embodiments of the present disclosure can also be described as follows:

A display device of one embodiment comprises a first substrate, a light emitting element disposed on a display area of the first substrate, an encapsulation layer disposed on the light emitting element, a second substrate disposed on the encapsulation layer and configured to face the first substrate, a dam structure disposed between the first substrate and the second substrate and disposed in a non-display area surrounding the display area, and a filling layer disposed to fill a space between the encapsulation layer and the second substrate, the dam structure comprising a matrix resin, and a capsule dispersed in the matrix resin and configured to include a redox dye.

The capsule may comprise a core and a shell surrounding the core, and the core may comprise a base resin and the redox dye dispersed in the base resin.

The capsule may further comprise a photosensitizer dispersed in the base resin.

The capsule may further comprise a sacrificial electron donor dispersed in the base resin.

The base resin may comprise a hydrophilic polymer, and the shell may comprise a crosslinked hydrophilic polymer.

The hydrophilic polymer and the crosslinked hydrophilic polymer may be selected from polyvinyl alcohol, polyethylene-vinyl alcohol, polyhydroxy alkyl methacrylate and a copolymer comprising one or more thereof.

The redox dye may comprise one or more selected from methylene blue, safranin, resorufin and indigo carmine.

The photosensitizer may comprise one or more selected from TiO₂ and nitrogen-doped TiO₂.

The sacrificial electron donor may comprise one or more selected from glycerol, glucose, and triethanolamine.

The dam structure may further comprise a moisture absorber dispersed in the dam structure.

The display device may further comprise a housing member disposed under the first substrate, and a plurality of light sources disposed on the housing member to overlap the non-display area.

The housing member may comprise a first portion disposed under the first substrate, and a second portion bent from the first portion and configured to cover at least a portion of a side surface of the second substrate, and each of the plurality of light sources may be disposed on the first portion.

The non-display area may be comprised of four surfaces to surround the display area, and each of the plurality of light sources may overlap at least three of the four surfaces of the non-display area.

Each of the plurality of light sources may be an LED light source.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a first substrate;
a light emitting element on a display area of the first substrate;
an encapsulation layer on the light emitting element;
a second substrate on the encapsulation layer, the second substrate facing the first substrate;
a dam structure between the first substrate and the second substrate and in a non-display area that surrounds the display area; and
a filling layer that fills a space between the encapsulation layer and the second substrate,
wherein the dam structure comprises a matrix resin, and a capsule dispersed in the matrix resin and configured to include a redox dye.

2. The display device of claim 1, wherein the capsule comprises a core and a shell surrounding the core, the core comprising a base resin and the redox dye dispersed in the base resin.

3. The display device of claim 2, wherein the capsule further comprises a photosensitizer dispersed in the base resin.

4. The display device of claim 2, wherein the capsule further comprises a sacrificial electron donor dispersed in the base resin.

5. The display device of claim 2, wherein the base resin comprises a hydrophilic polymer and the shell comprises a crosslinked hydrophilic polymer.

6. The display device of claim 5, wherein the hydrophilic polymer and the crosslinked hydrophilic polymer are selected from polyvinyl alcohol, polyethylene-vinyl alcohol, polyhydroxy alkyl methacrylate and a copolymer comprising one or more thereof.

7. The display device of claim 1, wherein the redox dye comprises one or more selected from methylene blue, safranin, resorufin and indigo carmine.

8. The display device of claim 3, wherein the photosensitizer comprises one or more selected from TiO₂ and nitrogen-doped TiO₂.

9. The display device of claim 4, wherein the sacrificial electron donor comprises one or more selected from glycerol, glucose, and triethanolamine.

10. The display device of claim 1 wherein the dam structure further comprises a moisture absorber dispersed in the dam structure.

11. The display device of claim 1, wherein the display device further comprises:
a housing member under the first substrate; and
a plurality of light sources on the housing member and overlapping the non-display area.

12. The display device of claim 11, wherein the housing member comprises a first portion under the first substrate, and a second portion bent from the first portion and covering at least a portion of a side surface of the second substrate, and
each of the plurality of light sources is on the first portion.

13. The display device of claim 11, wherein the non-display area comprises four surfaces that surround the display area, and each of the plurality of light sources overlaps at least three of the four surfaces of the non-display area.

14. The display device of claim 11, wherein each of the plurality of light sources is a light emitting diode light source.
